(19) United States
(12) Patent Application Publication
(10) Pub. No.: US 2026/0214828 A1
(43) Pub. Date: Jul. 23, 2026

(54) SERVER INSTALLATION STRUCTURE AND SERVER SYSTEM

(71) Applicant: SUZHOU METABRAIN INTELLIGENT TECHNOLOGY CO., LTD., Suzhou, Jiangsu (CN)

(72) Inventors: Xiaozheng LI, Suzhou, Jiangsu (CN); Jiajin YUAN, Suzhou, Jiangsu (CN); Li WANG, Suzhou, Jiangsu (CN); Xiuzhong YIN, Suzhou, Jiangsu (CN)

(21) Appl. No.: 19/127,715

(22) PCT Filed: Apr. 16, 2024
(86) PCT No.: PCT/CN2024/087891

§ 371 Date: May 6, 2025

(30) Foreign Application Priority Data
Oct. 9, 2023 (CN) 202311303066.3

(51) Int. Cl. H05K 7/14; H05K 7/18

(52) U.S. Cl. CPC H05K 7/1489; H05K 7/1401; H05K 7/183

(57) ABSTRACT

The present disclosure discloses a server installation structure and a server system, which is relative to the server technology field, and comprising: a server, configured to be installed in a cabinet, wherein the cabinet comprises an accommodating cavity and an opening, and the opening is communicated with the accommodating cavity; two opposite side surfaces of the server are respectively connected to a slide rail, the slide rail extends along a direction from the opening to interior of the accommodating cavity, and a first locking module and a second locking module are arranged on the slide rail at intervals along the direction from the opening to the interior of the accommodating cavity, and both the first locking module and the second locking module are switched between a locked state and an unlocked state; the first locking module comprises a first elastic piece, a locking member and a first spring, and the second locking module comprises a second elastic piece, wherein the first elastic piece is partially fixed to the slide rail, and a first gap is provided between the first elastic piece and the slide rail; the locking member is rotatably connected to the slide rail; one end of the first spring is connected to the first elastic piece; the other end of the first spring is connected to the locking member; and the second elastic piece is partially fixed to the slide rail; and an included angle is formed between a part of the second elastic piece and the slide rail; the second elastic piece is provided with a barrier member.

### CROSS-REFERENCE TO RELATED APPLICATION

The present disclosure claims the priority of Chinese patent application filed in CNIPA on Oct. 9, 2023, with the application number of 202311303066.3 and the application name of “SERVER INSTALLATION STRUCTURE AND SERVER SYSTEM”, the entire contents of which are incorporated into the present disclosure by reference.

### FIELD

The present disclosure belongs to the technical field of servers, and particularly relates to a server installation structure and a server system.

### BACKGROUND

With the development of science and technology, servers are widely used. Usually, the server needs to be installed in the cabinet, which is equipped with devices such as connecting wires. In the process of installing the server in the cabinet, the ball rail is usually connected to the server, the server is moved to the opening of the cabinet, and then the server is pushed into the cabinet through the ball rail. However, in the related art, the cost of the ball rail is high, which increases the cost of the installation of the server.

### SUMMARY

The purpose of the embodiments of the present disclosure is to provide a server installation structure and a server system, which at least solve the problem that the installation cost for the server is increased due to the high cost of the ball rail.

On a first aspect, the embodiments of the present disclosure provides a server installation structure, configured to install a server, and the server is configured to be installed in a cabinet, wherein the cabinet includes an accommodating cavity and an opening, and the opening is communicated with the accommodating cavity, and the server installation includes a first locking module, a second locking module and a slide rail;
two opposite side surfaces of the server are respectively connected to the slide rail, the slide rail extends along a direction from the opening to an inside of the accommodating cavity, and the first locking module and the second locking module are arranged on the slide rail at intervals along the direction from the opening to the inside of the accommodating cavity, and both the first locking module and the second locking module are switched between a locked state and an unlocked state;
the first locking module includes a first elastic piece, a locking member and a first spring, and the second locking module includes a second elastic piece, wherein the first elastic piece is partially fixed to the slide rail, and a first gap is provided between the first elastic piece and the slide rail; the locking member is rotatably connected to the slide rail; one end of the first spring is connected to the first elastic piece; the other end of the first spring is connected to the locking member; and the second elastic piece is partially fixed to the slide rail; and an included angle is formed between a part of the second elastic piece and the slide rail; the second elastic piece is provided with a barrier member; and
when the first locking module is in a locked state, a part of the locking member is located in the first gap, and the first spring is in a tension state; when the first locking module is in the unlocked state, the locking member is located outside the first gap, and the first spring is restored to an initial state; when the second locking module is in the locked state, an included angle is a first angle, and the barrier member is far away from the slide rail; when the second locking module is in the unlocked state, an included angle is a second angle, and the barrier member is close to the slide rail; wherein the first angle is greater than the second angle.

In some embodiments, the first elastic piece extends along an extension direction of the slide rail, and includes a first elastic part and a second elastic part, wherein the first elastic part is connected to the second elastic part, the first elastic part is close to the second locking module, and the second elastic part is far away from the second locking module;
the first elastic part is fixed on the slide rail, and a first gap is provided between the second elastic part and the slide rail; the locking member is rotatably connected to the slide rail; one end of the first spring is connected to the first elastic part; the other end of the first spring is connected to the locking member; and a barrier piece is arranged on the second elastic part;
when the first locking module is in the locked state, a part of the locking member is located in the first gap to increase the first gap, and the first spring is in a tension state; when the first locking module is in the unlocked state, the locking member is located outside the first gap, and the first spring restores to an initial state.

In some embodiments, the slide rail includes a body and an installation plate, wherein the body is connected to a side of the server in a sliding way, the installation plate is connected to the body, the first elastic part is fixed on the body, a gap is provided between the second elastic part and the body, the locking member is rotatably connected to the body, and a limiting slot is arranged on the installation plate; the limiting slot extends along the extension direction of the slide rail, the locking member is partially located in the limiting slot, and the limiting slot is provided with a first slot wall and a second slot wall which are opposite along the extension direction of the slide rail;
when the first locking module is in the locked state, a part of the locking member located in the limiting slot abuts against the first slot wall; when the first locking module is in the unlocked state, a part of the locking member located in the limiting slot abuts against the second slot wall.

In some embodiments, the locking member includes a locking part and a connecting part, the connecting part is L-shaped, the locking part is connected to one end of the connecting part, the connecting part is rotatably connected to the slide rail, and the connecting part is connected to the first spring;
when the first locking module is in the locked state, the locking part is located in the first gap, and the connecting part deflects relative to a slide rail position; when the first locking module is in the unlocked state, the locking part moves out of the first gap, and the connecting part is reset under an action of the first spring.

In some embodiments, a surface of the locking member facing the slide rail is provided with an avoidance slot, and the first spring part is located in the avoidance slot and connected to the locking member.

In some embodiments, the locking member is provided with a connecting hole, and the first spring is connected to the connecting hole.

In some embodiments, the second elastic part is provided with a concave part along a direction from the second elastic part to the slide rail;
when the first locking module is in the locked state, a part of the locking member is located in the first gap and between the concave part and the slide rail to increase the first gap.

In some embodiments, a first guide structure is arranged on the locking member, and when the locking member moves into the first gap and the first guide structure contacts with the concave part, the first guide part guides the locking member to move between the concave part and the slide rail.

In some embodiments, the second elastic sheet extends along an extension direction of the slide rail, and includes a third elastic part and a fourth elastic part, wherein the third elastic part is connected to the fourth elastic part, the third elastic part is fixed on the slide rail, an included angle is formed between the fourth elastic part and the slide rail, and the barrier member is arranged on a surface of the fourth elastic part away from the slide rail.
when the second locking module is in the locked state, the included angle between the fourth elastic part and the slide rail is a first angle, and the barrier member is far away from the slide rail; when the second locking module is in the unlocked state, the included angle between the fourth elastic part and the slide rail is a second angle, and the barrier member is close to the slide rail.

In some embodiments, a second guiding structure is arranged on one side of the barrier member close to the first locking module, and the second guiding structure is configured to guide the barrier member when the barrier member enters the accommodating cavity.

In some embodiments, the second locking module further includes a key, the key is fixed on the surface of the fourth elastic part away from the slide rail, and the key is located between the barrier member and the third elastic part.

In some embodiments, a third guiding structure is arranged on one side of the button away from the barrier member, and the third guiding structure is configured to guide the button when the server moves out of the accommodating cavity.

In some embodiments, a pressing mark is arranged on the key, and the pressing mark is configured to indicate that the key is pressed at the pressing mark.

In some embodiments, the second locking module further includes a second spring, one end of the second spring is connected to the slide rail and the other end of the second spring is connected to the key, and an expansion and contraction direction of the spring is the same as a pressing direction of the key.

In some embodiments, the fourth elastic part is provided with an avoidance hole, and the second spring passes through the avoidance hole.

In some embodiments, a sliding slot is arranged on the slide rail, and a fixing member is arranged on the side of the server, and the fixing member penetrates through the sliding slot, and a size of the sliding slot along the extension direction of the slide rail is larger than that of the fixing member, to make the sliding slot slide relative to the slide rail.

In some embodiments, a number of the sliding slots is two, and the two sliding slots are staggered.

On a second aspect, the embodiments of the present disclosure provides a server system, wherein the server system includes a cabinet and the server installation structure according to any one of above mentioned in the first aspect;
the cabinet includes an accommodating cavity and an opening, and the opening is communicated with the accommodating cavity;
when the server is moved to the opening and installed in the accommodating cavity, the first locking module and the second locking module are both located outside the accommodating cavity, the first locking module is in an unlocked state and the second locking module is in a locked state; when the first locking module moves into the accommodating cavity with the server and the second locking module is outside the accommodating cavity, both the first locking module and the second locking module are in a locked state; when the second locking module moves to the opening with the server, the second locking module is switched from a locked state to an unlocked state, so that the server and the second locking module can move into the accommodating cavity.

In some embodiments, when both the first locking module and the second locking module are located in the accommodating cavity, the first locking module is in a locked state and the second locking module is in a locked state;
when the server moves out of the accommodating cavity and the second locking module moves to the opening, the second locking module is switched from the locked state to the unlocked state.

In some embodiments, the cabinet is provided with a first direction, a second direction and a third direction which intersect, and a first column, a second column, a third column and a fourth column are arranged in the accommodating cavity, and the accommodating cavity is provided with a first cavity wall and a second cavity wall which are opposite to each other along the first direction, and the first column and the second column are arranged on the first cavity wall at intervals along the second direction, the third column and the fourth column are arranged on the second cavity wall at intervals along the second direction; the first column is opposite to the third column in the first direction; the second column is opposite to the fourth column in the first direction; a plurality of brackets are arranged between the first column and the second column and between the third column and the fourth column; and the brackets are distributed at intervals along the third direction;
when the first locking module moves into the accommodating cavity with the server, the bracket carries the server, the server slides relative to the bracket, and the bracket acts on the first locking module to make the first locking module in a locked state.

In some embodiments, when the first locking module and the second locking module are both located in the accommodating cavity, and the first locking module abuts against the second column or the fourth column, the second column or the fourth column blocks the first locking module, so that the first locking module no longer moves relative to the accommodating cavity.

In some embodiments, the bracket includes a top plate, a bottom plate and a connecting plate, wherein the top plate and the bottom plate are distributed at intervals, the connecting plate is located between the top plate and the bottom plate, and the connecting plates are respectively connected to the top plate and the bottom plate; a gap between the top plate and the bottom plate is configured to accommodate the server or a slide rail on the server; and the bottom plate is configured to act on the first locking module to make the first locking module in a locking state, and the connecting plate is configured to connect to the cabinet.

In some embodiments, the opening is provided with a cabinet door, and the cabinet door is movably connected to the cabinet.

In some embodiments, a universal wheel is arranged at a bottom of the cabinet.

In the embodiment of the present disclosure, because the opening of the cabinet is communicated with the accommodating cavity, the server may be installed in the accommodating cavity through the opening. Because the two opposite side surfaces of the server are respectively connected to slide rails, the slide rails extend along the direction from the opening to the inside of the accommodating cavity, when the server is moved to the opening, the server can partially extend into the accommodating cavity, and the server is pushed into the accommodating cavity through the slide rails. As the first locking module and the second locking module are arranged on the slide rail at intervals along the direction from the opening to the inside of the accommodating cavity, and both the first locking module and the second locking module are switched between the locked state and the unlocked state, once the server is moved to the opening in the process of installing the server, the first locking module and the second locking module are located outside the accommodating cavity, the first locking module is in the unlocked state, and the second locking module is in the locked state. So that the server can be continuously pushed into the accommodating cavity; in the process of continuously pushing the server, once the first locking module moves into the accommodating cavity with the server and the second locking module is outside the accommodating cavity, both the first locking module and the second locking module may be in a locked state and continue to push the server, so that when the second locking module moves to the opening with the server, the second locking module may be switched from a locked state to an unlocked state, so that the second locking module can enter the accommodating cavity. That is, in the embodiment of the present disclosure, the slide rail is installed on the side of the server, and the first locking module and the second locking module are arranged on the slide rail, so that the installation for the server can be realized; in addition, the ball rail is avoided to connected to the server, and only the first locking module and the second locking module are arranged on the slide rail, so that the installation cost for the server can be reduced.

### BRIEF DESCRIPTION OF THE DRAWINGS

FIG. 1 shows a schematic diagram of a server connecting slide rail provided by an embodiment of the present disclosure;

FIG. 2 shows one of the schematic diagrams of a locking module provided by an embodiment of the present disclosure;

FIG. 3 shows a schematic diagram of a bracket provided by an embodiment of the present disclosure;

FIG. 4 shows a schematic diagram of a cabinet provided by an embodiment of the present disclosure;

FIG. 5 shows a first schematic diagrams of a server installation structure provided by an embodiment of the present disclosure;

FIG. 6 shows an enlarged view at A in FIG. 5;

FIG. 7 shows a second schematic diagram of a server installation structure provided by an embodiment of the present disclosure;

FIG. 8 shows an enlarged view at B in FIG. 7;

FIG. 9 shows a schematic diagram of a second locking module provided by an embodiment of the present disclosure;

FIG. 10 shows a second schematic diagram of a first locking module provided by an embodiment of the present disclosure.

### REFERENCE NUMERAL

10, cabinet; 11, accommodation cavity; 12, opening; 101, universal wheel; 111, first column; 112, second column; 113, third column; 114, fourth column; 20, server; 201, fixing member; 30, slide rail; 301, sliding slot; 31, body; 32, installation plate; 321, limiting slot; 3211, first slot wall; 3212, second slot wall; 40, first locking module; 41, first elastic piece; 411, first elastic part; 412, second elastic part; 4121, concave part; 4122, barrier piece; 42, locking member; 421, locking part; 4211, first guide structure; 422, connecting part; 4201, avoidance slot; 4202, connecting hole; 43, first spring; 50, second locking module; 51, second elastic piece; 511, third elastic part; 512, fourth elastic part; 5121, avoidance hole; 513, barrier member; 5131, second guide structure; 52, key; 521, third guiding structure; 522, press mark; 53, second spring; 60, bracket; 61, top plate; 62, bottom plate; 63, connecting plate.

### DETAILED DESCRIPTION

The features of the terms “first” and “second” in the specification and claims of the present disclosure may explicitly or implicitly include one or more of these features. In the description of the present disclosure, unless otherwise specified, “plural” means two or more. In addition, “and/or” in the specification and claims means at least one of the connected objects, and the character “/”generally means that the contextual objects are in an “or” relationship.

In the description of the present disclosure, it should be understood that the terms “center”, “longitudinal direction”, “transverse direction”, “length”, “width”, “thickness”, “top”, “bottom”, “front”, “back”, “left”, “right”, “vertical” and “horizontal”. It is only for the convenience of describing the present disclosure and simplifying the description, and does not indicate or imply that the referred devices or elements must have a specific orientation, be constructed and operated in a specific orientation, so it cannot be understood as a limitation of the present disclosure.

In the description of the present disclosure, it should be noted that unless otherwise specified and limited, the terms “installation”, “link” and “connection” should be broadly understood, for example, they can be fixed connection, detachable connection or integrated connection; It can be a mechanical connection or an electrical connection; Can be directly connected, can also be indirectly connected through an intermediate medium, and can be connected inside two elements. For those skilled in the art, the specific meanings of the above terms in the present disclosure can be understood in specific circumstances.

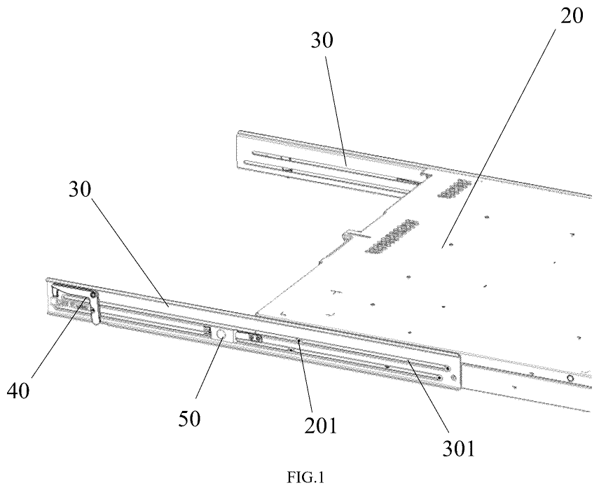

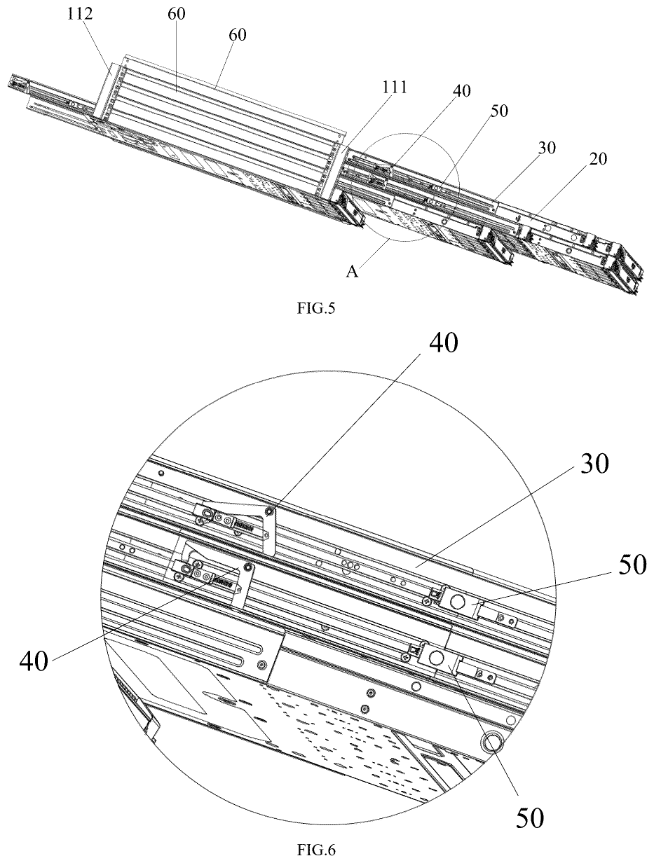

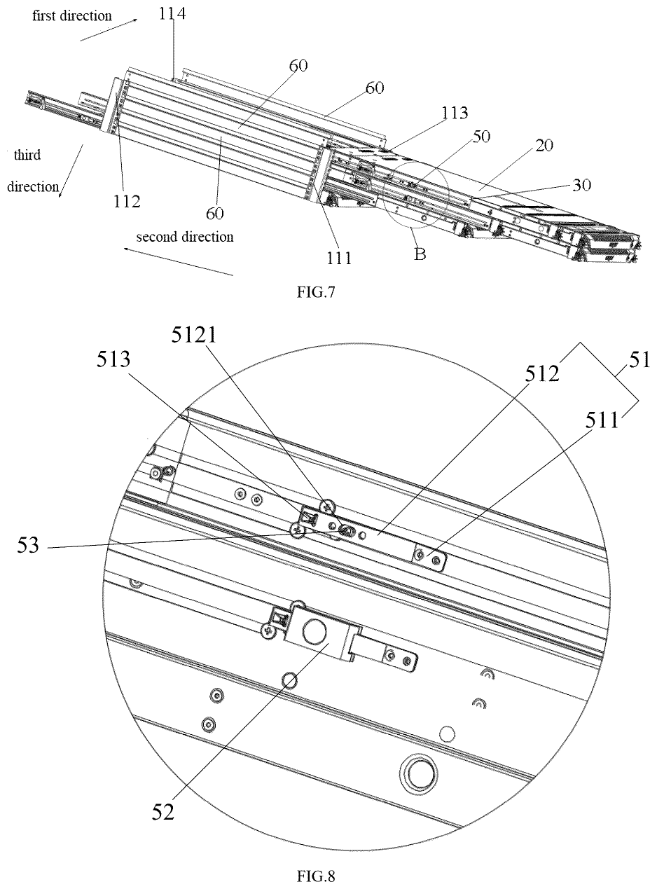

As shown in FIGS. 1 to 10, the server installation structure includes a first locking module 40, a second locking module 50 and a slide rail 30. A server 20, and the server 20 is configured to be installed in a cabinet 10. The cabinet 10 includes an accommodating cavity 11 and an opening 12, and the opening 12 communicates with the accommodating cavity 11. Two opposite sides of the server 20 are respectively connected to the slide rail 30, and the slide rail 30 extends along the direction from the opening 12 to the inside of the accommodating cavity 11. The first locking module 40 and the second locking module 50 are arranged on the slide rail 30 at intervals along the direction from the opening 12 to the inside of the accommodating cavity 11, and both the first locking module 40 and the second locking module 50 are switched between the locked state and the unlocked state. The first locking module 40 includes a first elastic piece 41, a locking member 42 and a first spring 43, and the second locking module 50 includes a second elastic piece 51. The first elastic piece 41 is partially fixed to the slide rail 30 with a first gap between the first elastic piece 41 and the slide rail 30. The locking member 42 is rotatably connected to the slide rail 30, and one end of the first spring 43 is connected to the first elastic piece 41, and the other end of the first spring 43 is connected to the locking member 42. The second elastic piece 51 is partially fixed on the slide rail 30, and an included angle is formed between the second elastic piece 51 and the slide rail 30, and the second elastic piece 51 is provided with a barrier member 513. When the first locking module 40 is in the locked state, the locking member 42 is partially located in the first gap, and the first spring 43 is in the tension state. When the first locking module 40 is in the unlocked state, the locking member 42 is located outside the first gap, and the first spring 43 restores to the initial state. When the second locking module 50 is in the locked state, the included angle is a first angle, and the barrier member 513 is far away from the slide rail 30. When the second locking module 50 is in the unlocked state, the included angle is a second angle, and the barrier member 513 is close to the slide rail 30. Wherein the first angle is greater than the second angle.

In the embodiment of the present disclosure, since the opening 12 of the cabinet 10 communicates with the accommodating cavity 11, the server 20 can be installed in the accommodating cavity 11 through the opening 12. Because the two opposite sides of the server 20 are connected to the slide rails 30 respectively, the slide rails 30 extend along the direction from the opening 12 to the inside of the accommodating cavity 11, when the server 20 is moved to the opening 12, the server 20 can partially extend into the accommodating cavity 11, and the server 20 is pushed into the accommodating cavity 11 through the slide rails 30. Because the first locking module 40 and the second locking module 50 are arranged on the slide rail 30 at intervals along the direction from the opening 12 to the inside of the accommodating cavity 11, both the first locking module 40 and the second locking module 50 switch between the locked state and the unlocked state, once the server 20 is moved to the opening 12 in the process of installing the server 20, both the first locking module 40 and the second locking module 50 are located outside the accommodating cavity 11. The first locking module 40 is in the unlocked state and the second locking module 50 is in the locked state, so that the server 20 can be pushed into the accommodating cavity 11 continuously. In the process of pushing the server 20 continuously, once the first locking module 40 moves into the accommodating cavity 11 with the server 20 and the second locking module 50 is outside the accommodating cavity 11, both the first locking module 40 and the second locking module 50 can be in the locked state. Continue to push the server 20, so that when the second locking module 50 moves to the opening 12 with the server 20, the second locking module 50 can switch from the locked state to the unlocked state, so that the second locking module 50 can enter the accommodating cavity 11. That is, in the embodiment of the present disclosure, the slide rail 30 is installed on the side of the server 20, and the first locking module 40 and the second locking module 50 are arranged on the slide rail 30, so that the installation of the server 20 can be realized. In addition, the ball rail is avoided to connected to the server 20, and only the first locking module 40 and the second locking module 50 are arranged on the slide rail 30, so that the installation cost of the server 20 can be reduced.

In addition, by arranging the first locking module 40 and the second locking module 50, the first locking module 40 includes the first elastic piece 41, the locking member 42 and the first spring 43, and the second locking module includes the second elastic piece 51, the cost of the first locking module 40 and the second locking module 50 is lower, and the cost of installing the server 20 is reduced.

In addition, in the embodiment of the present disclosure, slide rails 30 with various sizes can be designed for servers 20 with various sizes, as long as the slide rails 30 are adapted to the servers 20, so that the slide rails 30, the first locking module 40 and the second locking module 50 can be designed according to the slide rails 30, the first locking module 40 and the second locking module 50 of the present disclosure, so that the slide rail 30, the first locking module 40 and the second locking module 50 can be installed for servers 20 of various sizes, so that the slide rail 30, the first locking module 40 and the second locking module 50 on the server 20 are universal.

In addition, in the embodiment of the present disclosure, when both the first locking module 40 and the second locking module 50 are located in the accommodating cavity 11, the first locking module 40 is in a locked state and the second locking module 50 is in a locked state; When the server 20 moves out of the accommodating cavity 11 and the second locking module 50 moves to the opening 12, the second locking module 50 can be switched from the locked state to the unlocked state.

Through this arrangement, once the second locking module 50 enters the accommodating cavity 11, the second locking module 50 is in a locked state, so that the problem that the server 20 is detached from the accommodating cavity 11 when it is not necessary to remove the server 20 from the accommodating cavity 11 can be avoided. In addition, when the server 20 needs to be removed from the accommodating cavity 11, once the second locking module 50 moves to the opening 12, the second locking module 50 can be switched from the locked state to the unlocked state, so that the server 20 can continue to be separated from the accommodating cavity 11.

In addition, in some embodiments, as shown in FIG. 7, the cabinet 10 is provided with a first direction, a second direction and a third direction which intersect, and the accommodating cavity 11 is provided with a first column 111, a second column 112, a third column 113 and a fourth column 114. The accommodating cavity 11 is provided with a first cavity wall and a second cavity wall which are opposite to each other along the first direction, and the first column 111 and the second column 112 are arranged in the first cavity at intervals along the second direction. The third column 113 and the fourth column 114 are arranged on the second cavity wall at intervals along the second direction. The first column 111 is opposite to the third column 113 in the first direction, and the second column 112 is opposite to the fourth column 114 in the first direction. A plurality of brackets 60 are arranged between the first column 111 and the second column 112 and between the third column 113 and the fourth column 114, and the brackets 60 are distributed at intervals along the third direction. The bracket 60 extends in the direction from the opening 12 to the inside of the accommodating cavity 11; When the first locking module 40 moves into the accommodating cavity 11 with the server 20, the bracket 60 carries the server 20, and the server 20 slides relative to the bracket 60, and the bracket 60 acts on the first locking module 40 to make the first locking module 40 in a locked state.

Through this arrangement, after the server 20 is moved to the opening 12, the server 20 can partially extend into the accommodating cavity 11, and the slide rail 30 will enter the accommodating cavity 11 with the server 20, that is, the slide rail 30 and part of the server 20 will enter the bracket 60, so that the bracket 60 will bear the server 20, and the first locking module 40 will contact with the bracket 60, so that the bracket 60 will act on the first locking module 40 to make the first locking module. That is, the first locking module 40 is switched from the unlocked state to the locked state by the action of the bracket 60.

It should be noted that a number of the brackets 60 can be set according to actual needs, for example, the number of the brackets 60 is 10, and for another example, the number of the brackets 60 is 15. For the specific number of the brackets 60, the embodiment of the present disclosure is not limited here.

In addition, in the embodiment of the present disclosure, when the first locking module 40 and the second locking module 50 are both located in the accommodating cavity 11, and the first locking module 40 abuts against the second column 112 or the fourth column 114, the second column 112 or the fourth column 114 blocks the first locking module 40, so that the first locking module 40 does not move relative to the accommodating cavity 11. With this arrangement, once the first locking module 40 contacts with the second column 112 or the fourth column 114, the first locking module 40 will be blocked by the second column 112 or the fourth column 114 at this time, and the first locking module 40 will be fixed on the slide rail 30, so that the slide rail 30 will stop moving because the first locking module 40 is blocked, that is, the slide rail 30 is equivalent to being blocked, so that the slide rail 30 will not continue to move with the server 20, thus avoiding the problem that the slide rail 30 excessively extends into the accommodating cavity 11, which will affect the connecting wires, connecting terminals and other components in the accommodating cavity 11.

In addition, in some embodiments, as shown in FIG. 3, the bracket 60 includes a top plate 61, a bottom plate 62 and a connecting plate 63, wherein the top plate 61 and the bottom plate 62 are distributed at intervals, and the connecting plate 63 is located between the top plate 61 and the bottom plate 62 and connected to the top plate 61 and the bottom plate 62 respectively; the gap between the top plate 61 and the bottom plate 62 is configured to accommodate the server 20 or the slide rail 30 on the server 20, and the bottom plate 62 is configured to act on the first locking module 40, so that the first locking module 40 is in a locked state, and the connecting plate 63 is configured to connect to the cabinet 10.

With this arrangement, when the bracket 60 is installed in the cabinet 10, the connecting plate 63 can be connected to the cavity wall of the accommodating cavity 11 in the cabinet 10, thereby fixing the bracket 60 in the accommodating cavity 11. After the first locking module 40 enters the accommodating cavity 11, the first locking module 40 actually enters the gap between the top plate 61 and the bottom plate 62, so that the first locking module 40 contacts with the bottom plate 62, and the bottom plate 62 acts on the first locking module 40, so that the first locking module 40 switches from the unlocked state to the locked state.

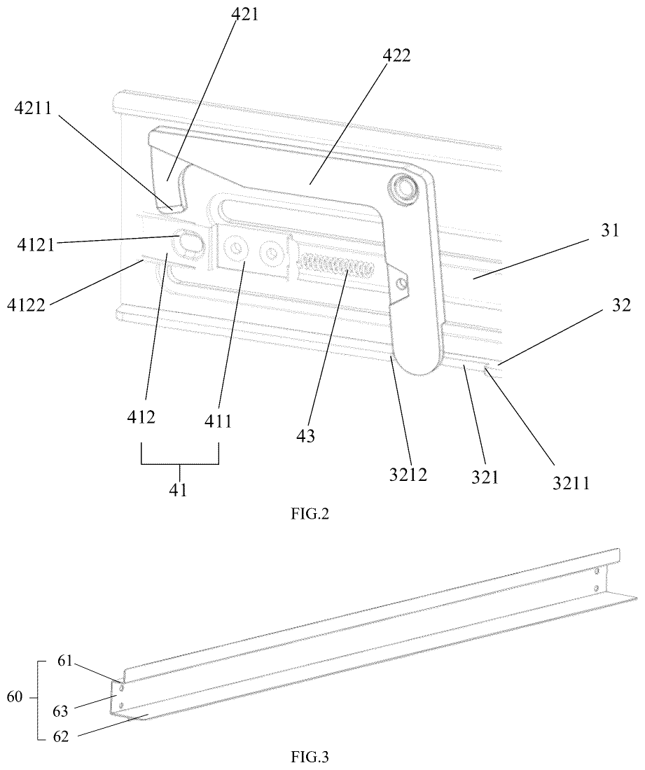

In addition, in some embodiments, as shown in FIGS. 2, 6 and 10, the first elastic piece 41 extends along the extension direction of the slide rail 30, and the first elastic piece 41 includes a first elastic part 411 and a second elastic part 412, and the first elastic part 411 and the second elastic part 412 are connected to each other, the first elastic part 411 is close to the second locking module 50 and the second elastic part 412 is far away from the second locking module 50; The first elastic part 411 is fixed to the slide rail 30, and a first gap is provided between the second elastic part 412 and the slide rail 30. The locking member 42 is rotatably connected to the slide rail 30, and one end of the first spring 43 is connected to the first elastic part 411, and the other end of the first spring 43 is connected to the locking member 42, and the second elastic part 412 is provided with a barrier piece 4122. When the first locking module 40 is in the locked state, the locking member 42 is partially located in the first gap to increase the first gap, and the first spring 43 is in the tension state. When the first locking module 40 is in the unlocked state, the locking member 42 is located outside the first gap, and the first spring 43 restores to the initial state.

With this arrangement, once the first locking module 40 moves into the accommodating cavity 11, the bracket 60 in the accommodating cavity 11 will act on the first locking module 40, so that the locking member 42 rotates relative to the slide rail 30, the locking member 42 pulls the first spring 43, and part of the locking member 42 enters the first gap, so that the first locking module 40 is in a locked state. Once the first locking module 40 moves to the outside of the accommodating cavity 11, the first spring 43 restores to the initial state, so that the first spring 43 drives the locking member 42 to reset, so that the locking member 42 moves out of the first gap, and the first locking module 40 is in an unlocked state.

It should be noted that when the bracket 60 includes a top plate 61, a bottom plate 62 and a connecting plate 63, once the first locking module 40 moves into the bracket 60, that is, the first locking module 40 moves into the gap between the bottom plate 62 and the top plate 61, the locking member 42 will contact with the bottom plate 62, so that the bottom plate 62 will exert force on the locking member 42 during the process of pushing the server 20, so that the locking member 42 rotates relative to the slide rail 30. And the locking member 42 drives the first spring 43, the locking member 42 partially enters the first gap between the second elastic part 412 and the slide rail 30, and the first locking module 40 switches from the unlocked state to the locked state.

Apparently, in the embodiment of the present disclosure, the first locking module 40 can also include a motor and a blocking rod connected to the motor, and the motor can drive the blocking rod to move. When the first locking module 40 is located outside the accommodating cavity 11, the motor drives the blocking rod to move in the first direction, and the blocking rod will not be blocked by the first column 111 or the third column 113, so that the first locking module 40 can enter the accommodating cavity 11. Once the first locking module 40 enters the accommodating cavity 11, the motor can drive the blocking rod to move, to make the blocking rod move in the second direction, and the blocking rod will be blocked by the second column 112 or the fourth column 114, so that the slide rail 30 is blocked and will not continue to move with the movement of the server 20.

In addition, in the embodiment of the present disclosure, the locking member 42 can be rotatably connected to the slide rail 30 in such a way that the locking member 42 is provided with a rotating hole, and a rotating piece penetrates through the rotating hole, and the rotating piece is embedded in the slide rail 30, so that the locking member 42 can rotate around the rotating piece. Wherein, the rotating piece includes but is not limited to rivets, screws, etc.

In addition, in some embodiments, as shown in FIG. 2, the slide rail 30 includes a body 31 and an installation plate 32, the body 31 is slidably connected to the side of the server 20, the installation plate 32 is connected to the body 31, and the first elastic part 411 is fixed to the body 31. There is a gap between the second elastic part 412 and the body 31, the locking member 42 is rotatably connected to the body 31, and the installation plate 32 is provided with a limiting slot 321. The limiting slot 321 extends along the extension direction of the slide rail 30, the locking member 42 is partially located in the limiting slot 321, and the limiting slot 321 is provided with a first slot wall 3211 and a second slot wall 3212 opposite to each other along the extension direction of the slide rail 30. When the first locking module 40 is in a locked state, a part of the locking member 42 located in the limiting slot 321 abuts against the first slot wall 3211. When the first locking module 40 is in the unlocked state, a part of the locking member 42 located in the limiting slot 321 abuts against the second slot wall 3212.

With this arrangement, the first slot wall 3211 and the second slot wall 3212 can limit the movement of the locking member 42, to prevent the locking member 42 from rotating excessively in the rotating process. Specifically, when the locking element 42 is acted by the bracket 60, the first locking module 40 is in a locked state, and the locking element 42 is blocked by the first slot wall 3211 to avoid excessive rotation of the locking element 42. When the locking element 42 is acted by the first spring 43, the first locking module 40 is in an unlocked state, and the locking element 42 is blocked by the second slot wall 3212 to avoid excessive rotation of the locking element 42.

In addition, in the embodiment of the present disclosure, as shown in FIG. 2, the locking member 42 includes a locking part 421 and a connecting part 422, the connecting part 422 is L-shaped, the locking part 421 is connected to one end of the connecting part 422, the connecting part 422 is rotatably connected to the slide rail 30, and the connecting part 422 is connected to a first spring 43; When the first locking module 40 is in the locked state, the locking part 421 is located in the first gap, and the connecting part 422 deflects relative to the slide rail 30. When the first locking module 40 is in the unlocked state, the locking part 421 moves out of the first gap, and the connecting part 422 is reset under the action of the first spring 43.

The connecting part 422 can be provided with a rotating hole, and the rotating piece can pass through the rotating hole and be embedded in the slide rail 30, so that the connecting part 422 is rotationally connected to the slide rail 30. The rotating piece includes but is not limited to rivets, screws, etc.

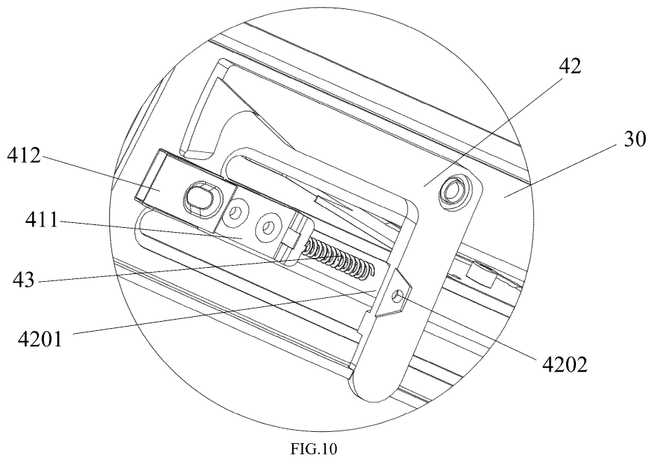

In addition, in some embodiments, as shown in FIG. 10, the surface of the locking member 42 facing the slide rail 30 is provided with an avoidance slot 4201, and the first spring 43 is partially located in the avoidance slot 4201 and connected to the locking member 42.

With this arrangement, when connecting the first spring 43 with the locking member 42, the first spring 43 can be partially located in the avoidance slot 4201, thus avoiding the problem of increasing the distance between the locking member 42 and the slide rail 30 in order to connect the first spring 43. If the avoidance slot 4201 is not provided in the locking member 42, when connecting the first spring 43 to the locking member 42, due to the inherent volume of the first spring 43, it is necessary to increase the distance between the locking member 42 and the slide rail 30 in order to realize the connection between the locking member 42 and the first spring 43, to make room for the first spring 43 to make the first spring 43 connected to the locking member 42. While the locking member 42 is provided with the avoidance slot 4201, the setting of the avoidance slot 4201 is equivalent to a role of avoiding the first spring 43 and avoiding the problem of increasing the distance between the locking member 42 and the slide rail 30.

In addition, in some embodiments, as shown in FIG. 10, the locking member 42 is provided with a connecting hole 4202, and the first spring 43 is connected to the connecting hole 4202. With this arrangement, when connecting the first spring 43 to the locking member 42, at this time, one end of the first spring 43 can be directly connected in the connecting hole 4202, thus facilitating the connection of the first spring 43 to the locking member 42.

It should be noted that when the locking member 42 is provided with the avoidance slot 4201, at this time, the connecting hole 4202 may be arranged at a slot bottom of the avoidance slot 4201.

In addition, in some embodiments, as shown in FIG. 2, the second elastic part 412 is provided with a concave part 4121 along the direction from the second elastic part 412 to the slide rail 30; When the first locking module 40 is in the locked state, the locking member 42 is partially located in the first gap, and is located between the concave part 4121 and the slide rail 30 to increase the first gap.

With this arrangement, when the first locking module 40 is in the locked state, the locking member 42 can rotate, so that part of the locking member 42 moves into the first gap and part of the locking member 42 moves between the concave part 4121 and the slide rail 30, so that the part of the locking member 42 is equivalent to spreading the gap between the concave part 4121 and the slide rail 30, and the gap between the concave part 4121 and the slide rail 30 is smaller than the first gap. Therefore, once part of the locking member 42 moves into the gap between the concave part 4121 and the slide rail 30, when the gap is spread, the first gap will be spread wider, so that the second elastic part 412 is more far away from the slide rail 30, and the distance between the barrier piece 4122 and the slide rail 30 is larger, so that the barrier piece 4122 can effectively contact with the second column 112 or the fourth column 114 in the accommodating cavity 11, and the first locking module 40 is prevented from moving further to make the slide rail 30 not move with the server 20 any more. That is, by arranging the concave part 4121 on the second elastic part 412, it can help the barrier piece 4122 to be limited in the accommodating cavity 11, so that the barrier piece 4122 is blocked, so that the slide rail 30 does not move with the server 20 any more, and the slide rail 30 is prevented from excessively extending into the accommodating cavity 11, which will affect components such as connecting wires or connecting terminals in the accommodating cavity 11.

In addition, in some embodiments, as shown in FIG. 2, the locking member 42 is provided with a first guide structure 4211, and the first guide structure 4211 guides the locking member 42 to move between the concave part 4121 and the slide rail 30 when the locking member 42 partially moves into the first gap and the first guide structure 4211 contacts with the concave part 4121.

By arranging the first guide structure 4211 on the locking member 42, once part of the locking member 42 enters the first gap and contacts with the concave part 4121 in the process of making the locking member 42 rotate relative to the slide rail 30, the first guide part can guide the locking member 42, so that the locking member 42 can easily move between the concave part 4121 and the slide rail 30, thereby facilitating the locking member 42 to spread the gap between the concave part 4121 and the slide rail 30.

It should be noted that the first guide structure 4211 can be provided with an inclined surface, that is, an inclined surface is provided on the locking member 42, so that after the inclined surface contacts with the concave portion 4121, the locking member 42 can easily enter the gap between the concave portion 4121 and the slide rail 30 due to the inclined function of the inclined surface.

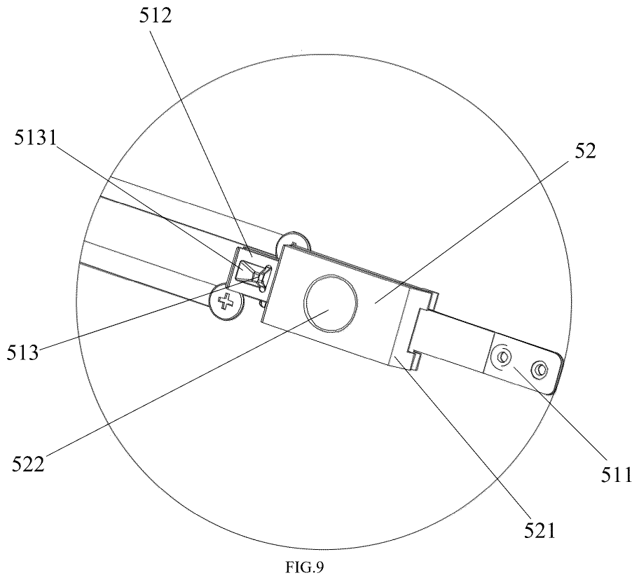

In addition, in the embodiment of the present disclosure, as shown in FIGS. 8 and 9, the second locking module 50 may include a second elastic piece 51 extending along the extension direction of the slide rail 30, and the second elastic piece 51 includes a third elastic part 511 and a fourth elastic part 512, the third elastic part 511 are connected to the fourth elastic part 512 and the third elastic part 511 are fixed to the slide rail 30, and an included angle is provided between the fourth elastic part 512 and the slide rail 30. The surface of the fourth elastic part 512 away from the slide rail 30 is provided with a barrier member 513, the third elastic part 511 is far away from the first locking module 40, and the fourth elastic part 512 is close to the first locking module 40. When the second locking module 50 is in the locked state, the included angle between the fourth elastic part 512 and the slide rail 30 is a first angle, and the barrier member 513 is far away from the slide rail 30. When the second locking module 50 is in the unlocked state, the included angle between the fourth elastic part 512 and the slide rail 30 is a second angle, and the barrier member 513 is close to the slide rail 30. Wherein the first angle is greater than the second angle.

When the included angle between the fourth elastic part 512 and the slide rail 30 is the first angle, the barrier member 513 is far away from the slide rail 30, and the distance between the barrier member 513 and the slide rail 30 is relative large, so that the barrier member 513 can be effectively blocked by the first column 111 or the third column 113. When the included angle between the fourth elastic part 512 and the slide rail 30 is the second angle, the barrier member 513 is close to the slide rail 30, and the distance between the barrier member 513 and the slide rail 30 is relative small, so that the barrier member 513 can pass through the first column 111 or the third column 113.

In addition, in some embodiments, as shown in FIG. 9, one side of the barrier member 513 close to the first locking module 40 is provided with a second guiding structure 5131, and the second guiding structure 5131 is configured to guide the barrier member 513 when the barrier member 513 enters the accommodating cavity 11.

With this arrangement, once the second locking module 50 moves to the opening 12 in the process of pushing the server 20 into the accommodating cavity 11, if the first column 111 or the third column 113 is arranged in the accommodating cavity 11, at this time, when the barrier member 513 moves to the first column 111 or the third column 113, the first column 111 or the third column 113 will block the continuous movement of the barrier member 513. The second guiding structure 5131 is provided on the barrier member 513. Once the barrier member 513 contacts with the first column 111 or the third column 113, at this time, the second guiding structure 5131 will play a guiding role, so that the barrier member 513 is less blocked by the first column 111 or the third column 113, which facilitates the barrier member 513 to enter the accommodating cavity 11 with the server 20.

It should be noted that the second guide structure 5131 can be an inclined surface, that is, an inclined surface is arranged on the side of the barrier member 513 close to the first locking module 40. At this time, once the barrier member 513 contacts with the first column 111 or the third column 113, the blocking force between the barrier member 513 and the first column 111 or the third column 113 is relative small due to the action of the inclined surface, so that the barrier member 513 can easily enter the accommodating cavity 11.

In addition, in some embodiments, as shown in FIG. 9, the second locking module 50 further includes a key 52, and the key 52 is fixed on the surface of the fourth elastic part 512 away from the slide rail 30, and the key 52 is located between the barrier member 513 and the third elastic part 511.

Once the second locking module 50 moves to the opening 12, the key 52 can be pressed to make the key 52 apply force to the third elastic part 511, so that the key 52 is close to the slide rail 30, thus the second locking module 50 is in an unlocked state, allowing the key 52 to enter the accommodating cavity 11. When the server 20 needs to be pushed out of the accommodating cavity 11 for maintenance, the key 52 can be moved to the outside of the accommodating cavity 11, and the barrier member 513 is located inside the accommodating cavity 11, that is, the first column 111 or the third column 113 is located between the key 52 and the barrier member 513, so that the barrier member 513 can be blocked by the first column 111 or the third column 113 to prevent the barrier member 513 from moving outside the accommodating cavity 11.

In addition, in some embodiments, as shown in FIG. 9, one side of the key 52 away from the barrier member 513 is provided with a third guiding structure 521, and the third guiding structure 521 is configured to guide the key 52 when the server 20 is moved out of the accommodating cavity 11.

With this arrangement, when the server 20 is moved out of the accommodating cavity 11, it may be necessary to move the key 52 out of the accommodating cavity 11, therefore the third guiding structure 521 is arranged on the side of the key 52 away from the barrier member 513. In the process of moving out the server 20, once the key 52 contacts with the first column 111 or the third column 113 of the accommodating cavity 11, the third guiding structure 521 can play a guiding role. After the key 52 contacts with the first column 111 or the third column 113, the blocking force of the first column 111 or the third column 113 on the key 52 is reduced, which is conductive to the key 52 being moved out of the accommodating cavity 11.

In addition, in some embodiments, as shown in FIG. 9, the key 52 is provided with a pressing mark 522, and the pressing mark 522 is configured to indicate that the key 52 is pressed at the pressing mark 522. With this arrangement, when the key 52 needs to be pressed, the user can directly press the pressing mark 522, thereby achieving the pressing of the key 52. That is, by setting the pressing mark 522, it is equivalent to a guiding role to the user, so that the user can clearly know the pressing position on the key 52.

It should be noted that the pressing mark 522 may be a pressing slot, a pressing boss, or a spray-painted pattern. For the specific type of the pressing mark 522, the embodiment of the present disclosure is not limited here.

In addition, in some embodiments, as shown in FIGS. 8 and 9, the second locking module 50 further includes a second spring 53. One end of the second spring 53 is connected to the slide rail 30, and the other end of the second spring 53 is connected to the key 52. The expansion and contraction direction of the spring is the same as the pressing direction of the key 52.

With this arrangement, after the key 52 is pressed, the key 52 can drive the second spring 53 to be pressed, so that once the force of pressing the key 52 is cancelled, the second spring 53 will drive the key 52 to reset, and the key 52 will drive the fourth elastic part 512 to move, so that the fourth elastic part 512 is far away from the slide rail 30. That is, by arranging the second spring 53, it is equivalent to supplementing the fourth elastic part 512 with the second spring 53, so that the fourth elastic part 512 can drive the barrier member 513 to be farther away from the slide rail 30.

In addition, in the embodiment of the present disclosure, when the key 52 is provided with the pressing mark 522, the pressing mark 522 may be opposite to the position of the second spring 53.

In addition, in some embodiments, as shown in FIG. 8, the fourth elastic part 512 is provided with an avoidance hole 5121, and the second spring 53 passes through the avoidance hole 5121. Through this arrangement, the second spring 53 can directly pass through the avoidance hole 5121, which is equivalent to the existence of an avoidance space in the fourth elastic part 512 to avoid the second spring 53, thus facilitating the connection between the second spring 53 and the key 52 and the installation of the second spring 53 on the slide rail 30.

In addition, in some embodiments, as shown in FIG. 1, the slide rail 30 is provided with a sliding slot 301, and the side of the server 20 is provided with a fixing member 201. The fixing member 201 penetrates through the sliding slot 301, and the size of the sliding slot 301 along the extension direction of the slide rail 30 is larger than that of the fixing member 201, so that the sliding slot 301 can slide relative to the slide rail 30. With this arrangement, on the one hand, the fixing member 201 can move relative to the sliding slot 301, and on the other hand, the fixing member 201 can also play a fixing role, to make the slide rail 30 be fixed on the server 20.

It should be noted that in the embodiment of the present disclosure, the fixing member 201 includes but is not limited to screws, rivets, pins, etc.

In addition, in some embodiments, a number of the sliding slots 301 is two, and the two sliding slots 301 are staggered. With this arrangement, the slide rail 30 can slide more smoothly relative to the server 20, and the length of the sliding slot 301 can be set according to the actual needs, and the two sliding slots 301 are staggered, so that the weak parts on the slide rail 30 can be avoided. It should be noted that when the number of sliding slots 301 is two, at this time, the lengths of the two sliding slots 301 are the same.

Apparently, in the embodiment of the present disclosure, the number of sliding slots 301 can be set according to actual needs, for example, the number of sliding slots 301 is three, and for another example, the number of sliding slots 301 is four. For the specific number of sliding slots 301, the embodiment of the present disclosure is not limited here.

In addition, in some embodiments, the opening 12 is provided with a cabinet door (not shown in the figure) which is movably connected to the cabinet 10.

By setting the cabinet door, the cabinet door can be closed after the server 20 is installed in the accommodating cavity 11, so that the cabinet door can protect the server 20 in the cabinet 10, and can be opened when the server 20 needs to be maintained. Wherein, the cabinet door and cabinet 10 can be connected by hinges, so that the cabinet door and cabinet 10 can be movably connected. Apparently, the cabinet door and cabinet 10 can also be connected by rotating shafts. The embodiment of the present disclosure is not limited to the manner in which the cabinet door is movably connected to the cabinet 10.

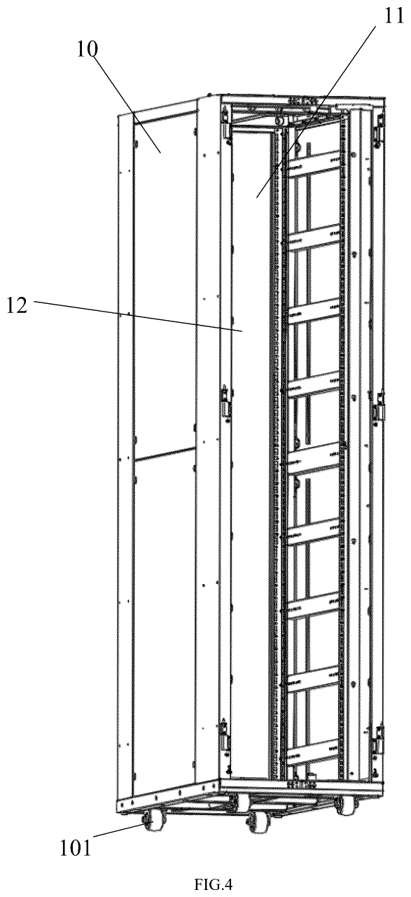

In addition, in some embodiments, as shown in FIG. 4, a bottom of the cabinet 10 is provided with a universal wheel 101. By setting the universal wheel 101, when the cabinet 10 needs to be moved, the cabinet 10 can be directly pushed, and the cabinet 10 can be moved through the universal wheel 101. That is, by providing the universal wheel 101, it is convenient for the cabinet 10 to move.

It should be noted that the number of universal wheels 101 can be set according to actual needs, for example, the number of universal wheels 101 is four, and for another example, the number of universal wheels 101 is eight. In this regard, the embodiments of the present disclosure are not limited here.

With reference to FIG. 1, the application of the server 20 system provided by the embodiment of the present disclosure will be described in detail below.

When the server 20 needs to be installed in the accommodating cavity 11 of the cabinet 10, at this time, the server 20 can be moved to the opening 12 and partially extended into the opening 12, and then the server 20 can be pushed in the direction from the opening 12 to the accommodating cavity 11, and in this process, the server 20 will enter the accommodating cavity 11, and the slide rail 30 will also enter the accommodating cavity 11. When the first locking module 40 does not enter the accommodating cavity 11, the first locking module 40 is in an unlocked state, that is, the locking member 42 does not rotate, and the locking member 42 does not enter the first gap between the second elastic part 412 and the body 31 of the slide rail 30, and the second locking module 50 is in a locked state. When the server 20 is continuously pushed to make the first locking module 40 enter the accommodating cavity 11, specifically, the slide rail 30 and the first locking module 40 both enter the bracket 60, that is, the slide rail 30 and the first locking module 40 enter between the top plate 61 and the bottom plate 62 of the bracket 60, at this time, the bottom plate 62 will exert force on the locking member 42, and the bottom plate 62 will make the locking member 42 rotate relative to the slide rail 30 due to the pushing action, and after the locking member 42 rotates, the first spring 43 will be driven to stretch, and the locking part 421 of the locking part 42 will enter the first gap between the second elastic part 412 and the slide rail 30 due to the rotation of the locking part 42. The second elastic part 412 is provided with a concave part 4121, and the locking part 421 will enter the gap between the concave part 4121 and the slide rail 30 under the guidance of the first guiding part, so that the locking part 421 will spread the gap between the concave part 4121 and the slide rail 30, so that the first gap can be further increased, and the second elastic part 412 is far away from the slide rail 30, and the barrier piece 4122 on the second elastic part 412 is far away from the slide rail 30. In the process of continuously pushing the server 20, once the second locking module 50 moves to the opening 12, at this time, the barrier member 513 on the fourth elastic part 512 of the second locking module 50 will contact with the first column 111 or the third column 113, and the barrier member 513 is provided with the second guiding structure 5131. Once the barrier member 513 contacts with the first column 111 or the third column 113, at this time, the second guiding structure 5131 will play a guiding role, so that the obstruction of the first column 111 or the third column 113 to the barrier member 513 will be reduced, allowing the barrier member 513 to continue moving and entering into the accommodating cavity 11. During the movement of the barrier member 513, the first column 111 or the third column 113 will press the barrier member 513, reducing the distance between the fourth elastic part 512 and the slide rail 30.

However, after the barrier member 513 completely enters the accommodating cavity 11, that is, the barrier member 513 has passed through the first column 111 or the third column 113, the fourth elastic part 512 will restore to the initial state due to its own elasticity. The fourth elastic part 512 is fixed with a key 52, and the key 52 will be blocked by the first column 111 or the third column 113. At this time, the user needs to press the key 52, so that by pressing the key 52, force is applied to the fourth elastic part 512, reducing the distance between the fourth elastic part 512 and the slide rail 30, thereby reducing the distance between the key 52 and the slide rail 30, allowing the key 52 to enter the accommodating cavity 11 through the first column 111 or the third column 113. If the key 52 is connected to the second spring 53, the second spring 53 will also support the key 52, ensuring that the distance between key 52 and the slide rail 30 is large enough when the key 52 has not entered the accommodating cavity 11, and the key 52 is blocked by the first column 111 or the third column 113. At this time, the second locking module 50 can be considered to be in a locked state. Once the key 52 is pressed, and the key 52 completely enters the accommodating cavity 11, the server 20 can be pushed continuously, allowing the server 20 to continuously enter the accommodating cavity 11. In this process, once the server 20 is pushed to make the first locking module 40 move to the second column 112 or the fourth column 114, at this time, the barrier piece 4122 will be blocked by the second column 112 or the fourth column 114, preventing the barrier piece 4122 from continuing to move, and thus the slide rail 30 will not continue to move. The slide rail 30 is connected to the server 20 in a sliding way, that is, the slide rail 30 is provided with a sliding slot 301, and the server 20 is provided with a fixing part 201. After the barrier piece 4122 is blocked, the slide rail 30 is blocked, so that during the process of the server 20 being continuously pushed into the accommodating cavity 11, the server 20 continues to move relative to the slide rail 30, that is, the fixing part 201 slides in the sliding slot 301, until the server 20 is pushed to the appropriate position, and the barrier piece 4122 is blocked by the second column 112 or the fourth column 114, avoiding the slide rail 30 from affecting the connecting lines or connecting terminals and other components in the accommodating cavity 11.

When it is necessary to pull the server 20 out of the accommodating cavity 11, at this time, force can be applied to the server 20, so that the server 20 will move outside the accommodating cavity 11. While the server 20 continues to move to the outside of the accommodating cavity 11, once the key 52 moves to the first column 111 or the third column 113, the first column 111 or the third column 113 will block the key 52, but the key 52 is provided with a third guiding structure 521, which can play a guiding role once the key 52 contacts with the first column 111 or the third column 113 of the accommodating cavity 11. After the key 52 contacts with the first column 111 or the third column 113, the blocking force of the first column 111 or the third column 113 to the key 52 is reduced, and the key 52 can be moved out of the accommodating cavity 11. When the key 52 is located outside the accommodating cavity 11 through the first column 111 or the third column 113, the barrier member 513 will be close to the first column 111 or the third column 113, and the first column 111 or the third column 113 will only be located between the key 52 and the barrier member 513 due to the presence of the barrier member 512, that is, the barrier member 513 is blocked by the first column 111 or the third column 113, so that the slide rail 30 will not move with the movement of the server 20. At this time, the server 20 will continue to be pulled out by continuing to apply force to the server 20 and pulling the server 20 to the outside of the accommodating cavity 11, while the slide rail 30 will always be located in the accommodating cavity 11 because the barrier member 513 is blocked by the first column 111 or the third column 113. The fixing member 201 on the server 20 will move relative to the sliding slot 301 on the slide rail 30. Therefore, the server 20 can be pulled out more, which is conducive to the maintenance of the server 20 after being pulled out more. Moreover, because the server 20 is pulled out more, the server 20 will not be affected by other servers 20 in the cabinet 10, resulting in the problem of difficult maintenance.

In the embodiment of the present disclosure, since the opening 12 of the cabinet 10 communicates with the accommodating cavity 11, the server 20 can be installed in the accommodating cavity 11 through the opening 12. Because the two opposite sides of the server 20 are connected to the slide rails 30 respectively, the slide rails 30 extend along the direction from the opening 12 to the inside of the accommodating cavity 11, when the server 20 is moved to the opening 12, the server 20 can partially extend into the accommodating cavity 11, and the server 20 is pushed into the accommodating cavity 11 through the slide rails 30. Because the first locking module 40 and the second locking module 50 are arranged on the slide rail 30 at intervals along the direction from the opening 12 to the inside of the accommodating cavity 11, both the first locking module 40 and the second locking module 50 switch between the locked state and the unlocked state, once the server 20 is moved to the opening 12 in the process of installing the server 20, at this time, both the first locking module 40 and the second locking module 50 are located outside the accommodating cavity 11. The first locking module 40 is in the unlocked state and the second locking module 50 is in the locked state, so that the server 20 can be pushed into the accommodating cavity 11 continuously. In the process of pushing the server 20 continuously, once the first locking module 40 moves into the accommodating cavity 11 with the server 20 and the second locking module 50 is outside the accommodating cavity 11, both the first locking module 40 and the second locking module 50 can be in the locked state. Continue to push the server 20, so that when the second locking module 50 moves to the opening 12 with the server 20, the second locking module 50 can switch from the locked state to the unlocked state, allowing the second locking module 50 to enter the accommodating cavity 11. That is, in the embodiment of the present disclosure, the slide rail 30 is installed on the side of the server 20, and the first locking module 40 and the second locking module 50 are arranged on the slide rail 30, so that the installation of the server 20 can be realized. In addition, the ball rail is avoided to connected to the server 20, and only the first locking module 40 and the second locking module 50 are arranged on the slide rail 30, so that the installation cost of the server 20 can be reduced.

An embodiment of the present disclosure provides a server 20 system, which includes a cabinet 10 and a server 20 installation structure in any of the above embodiments. The cabinet 10 includes an accommodating cavity 11 and an opening 12, and the opening 12 communicates with the accommodating cavity 11. When the server 20 is moved to the opening 12 and installed in the accommodating cavity 11, both the first locking module 40 and the second locking module 50 are located outside the accommodating cavity 11, with the first locking module 40 in the unlocked state and the second locking module 50 in the locked state. When the first locking module 40 moves into the accommodating cavity 11 with the server 20 and the second locking module 50 is outside the accommodating cavity 11, both the first locking module 40 and the second locking module 50 are in locked state. When the second locking module 50 moves to the opening 12 with the server 20, the second locking module 50 can be switched from the locked state to the unlocked state, allowing the server 20 and the second locking module 50 to move into the accommodating cavity 11.

In addition, in the embodiment of the present disclosure, when both the first locking module 40 and the second locking module 50 are located in the accommodating cavity 11, the first locking module 40 is in a locked state and the second locking module 50 is in a locked state; When the server 20 moves out of the accommodating cavity 11 and the second locking module 50 moves to the opening 12, the second locking module 50 can be switched from the locked state to the unlocked state.

In addition, in the embodiment of the present disclosure, the cabinet 10 is provided with a first direction, a second direction and a third direction that intersect, and a first column 111, a second column 112, a third column 113 and a fourth column 114 are arranged in the accommodating cavity 11, and the accommodating cavity 11 is provided with a first cavity wall and a second cavity wall opposite to each other along the first direction, and the first column 111 and the third column 113 are arranged on the first cavity wall at intervals along the second direction. The second column 112 and the fourth column 114 are arranged on the second cavity wall at intervals along the second direction; the first column 111 and the second column 112 are opposite in the first direction; the third column 113 and the fourth column 114 are opposite in the first direction; a plurality of brackets 60 are arranged between the first column 111 and the second column 112 and between the third column 113 and the fourth column 114; the brackets 60 are distributed at intervals along the third direction; and the brackets 60 extend along the direction from the opening 12 to the inside of the accommodating cavity 11; when the first locking module 40 moves into the accommodating cavity 11 with the server 20, the bracket 60 carries the server 20, and the server 20 slides relative to the bracket 60, and the bracket 60 acts on the first locking module 40 to make the first locking module 40 in a locked state.

In addition, in the embodiment of the present disclosure, when the first locking module 40 and the second locking module 50 are both located in the accommodating cavity 11, and the first locking module 40 abuts against the second column 112 or the fourth column 114, the second column 112 or the fourth column 114 blocks the first locking module 40, so that the first locking module 40 does not move relative to the accommodating cavity 11.

In addition, in the embodiment of the present disclosure, the bracket 60 includes a top plate 61, a bottom plate 62 and a connecting plate 63, the top plate 61 and the bottom plate 62 are spaced apart from each other, and the connecting plate 63 is located between the top plate 61 and the bottom plate 62, the connecting plate 63 is respectively connected to the top plate 61 and the bottom plate 62. The gap between the top plate 61 and the bottom plate 62 is configured to accommodate the server 20 or the slide rail 30 on the server 20, and the bottom plate 62 is configured to act on the first locking module 40 to make the first locking module to be in the locked state, and the connecting plate 63 is configured to connect to the cabinet 10.

In addition, in the embodiment of the present disclosure, the opening 12 is provided with a cabinet 10 door, and the cabinet 10 door is movably connected to the cabinet 10.

In addition, in the embodiment of the present disclosure, the bottom of the cabinet 10 is provided with a universal wheel 101. Wherein, the number of universal wheels 101 can be set according to actual needs, for example, the number of universal wheels 101 is four, and for another example, the number of universal wheels 101 is eight, which is not limited in this embodiment of the present disclosure.

In the description of this specification, descriptions referring to the terms “one embodiment”, “some embodiments”, “exemplary embodiments”, “examples”, “specific examples” or “some examples” mean that specific features, structures, materials or characteristics described in connection with this embodiment or example are included in at least one embodiment or example of the present disclosure. In this specification, the schematic expressions of the above terms do not necessarily refer to the same embodiment or example. Moreover, the specific features, structures, materials or characteristics described may be combined in any one or more embodiments or examples in a suitable manner.

Although the embodiments of the present disclosure have been shown and described, those skilled in the art can understand that many changes, modifications, substitutions and variations can be made to these embodiments without departing from the principles and purposes of the present disclosure, and the scope of the present disclosure is defined by the claims and their equivalents.

1. A server installation structure, configured to install a server, and the server is configured to be installed in a cabinet, wherein the cabinet comprises an accommodating cavity and an opening, and the opening is communicated with the accommodating cavity, and the server installation comprises a first locking module, a second locking module and a slide rail;
two opposite side surfaces of the server are respectively connected to the slide rail, the slide rail extends along a direction from the opening to interior of the accommodating cavity, and the first locking module and the second locking module are arranged on the slide rail at intervals along the direction from the opening to the interior of the accommodating cavity, and both the first locking module and the second locking module are switched between a locked state and an unlocked state;
the first locking module comprises a first elastic piece, a locking member and a first spring, and the second locking module comprises a second elastic piece, wherein the first elastic piece is partially fixed to the slide rail, and a first gap is provided between the first elastic piece and the slide rail; the locking member is rotatably connected to the slide rail; one end of the first spring is connected to the first elastic piece; the other end of the first spring is connected to the locking member; and the second elastic piece is partially fixed to the slide rail; and an included angle is formed between a part of the second elastic piece and the slide rail; the second elastic piece is provided with a barrier member; and
when the first locking module is in the locked state, a part of the locking member is located in the first gap, and the first spring is in a tension state; when the first locking module is in the unlocked state, the locking member is located outside the first gap, and the first spring is restored to an initial state; when the second locking module is in the locked state, the included angle is a first angle, and the barrier member is far away from the slide rail; when the second locking module is in the unlocked state, the included angle is a second angle, and the barrier member is close to the slide rail; wherein the first angle is greater than the second angle.

2. The server installation structure according to claim 1, wherein the first elastic piece extends along an extension direction of the slide rail, and the first elastic piece comprises a first elastic part and a second elastic part, the first elastic part is connected to the second elastic part, the first elastic part is close to the second locking module, and the second elastic part is far away from the second locking module;
the first elastic part is fixed on the slide rail, and the first gap is provided between the second elastic part and the slide rail; the locking member is rotatably connected to the slide rail;
one end of the first spring is connected to the first elastic part; the other end of the first spring is connected to the locking member; and a barrier piece is arranged on the second elastic part;
when the first locking module is in the locked state, a part of the locking member is located in the first gap to increase the first gap, and the first spring is in the tension state; when the first locking module is in the unlocked state, the locking member is located outside the first gap, and the first spring is restored to the initial state.

3. The server installation structure according to claim 2, wherein the slide rail comprises a body and an installation plate, the body is connected to a side of the server in a sliding way, the installation plate is connected to the body, the first elastic part is fixed on the body, a gap is provided between the second elastic part and the body, the locking member is rotatably connected to the body, and a limiting slot is arranged on the installation plate; the limiting slot extends along the extension direction of the slide rail, the locking member is partially located in the limiting slot, and the limiting slot is provided with a first slot wall and a second slot wall which are opposite along the extension direction of the slide rail;
when the first locking module is in the locked state, a part of the locking member located in the limiting slot abuts against the first slot wall; when the first locking module is in the unlocked state, a part of the locking member located in the limiting slot abuts against the second slot wall.

4. The server installation structure according to claim 2, wherein the locking member comprises a locking part and a connecting part, the connecting part is L-shaped, the locking part is connected to one end of the connecting part, the connecting part is rotatably connected to the slide rail, and the connecting part is connected to the first spring;
when the first locking module is in the locked state, the locking part is located in the first gap, and the connecting part deflects relative to a position of the slide rail; when the first locking module is in the unlocked state, the locking part moves out of the first gap, and the connecting part is reset under an action of the first spring.

5. The server installation structure according to claim 2, wherein a surface of the locking member facing the slide rail is provided with an avoidance slot, and the first spring is partially located in the avoidance slot and connected to the locking member.

6. The server installation structure according to claim 2, wherein the locking member is provided with a connecting hole, and the first spring is connected to the connecting hole.

7. The server mounting structure according to claim 2, wherein the second elastic part is provided with a concave part along a direction from the second elastic part to the slide rail;
when the first locking module is in the locked state, a part of the locking member is located in the first gap and between the concave part and the slide rail to increase the first gap.

8. The server installation structure according to claim 7, wherein a first guide structure is arranged on the locking member, and when the locking member partially moves into the first gap and the first guide structure contacts with the concave part, the first guide part guides the locking member to move between the concave part and the slide rail.

9. The server installation structure according to claim 1, wherein the second elastic piece extends along an extension direction of the slide rail, and the second elastic piece comprises a third elastic part and a fourth elastic part, the third elastic part is connected to the fourth elastic part, the third elastic part is fixed on the slide rail, the included angle is formed between the fourth elastic part and the slide rail, and the barrier member is arranged on a surface of the fourth elastic part away from the slide rail; the third elastic part is far away from the first locking module, and the fourth elastic part is close to the first locking module;
when the second locking module is in the locked state, the included angle between the fourth elastic part and the slide rail is the first angle, and the barrier member is far away from the slide rail; when the second locking module is in the unlocked state, the included angle between the fourth elastic part and the slide rail is the second angle, and the barrier member is close to the slide rail.

10. The server installation structure according to claim 9, wherein a second guiding structure is arranged on one side of the barrier member close to the first locking module, and the second guiding structure is configured to guide the barrier member when the barrier member enters the accommodating cavity.

11. The server installation structure according to claim 9, wherein the second locking module further comprises a key, the key is fixed on the surface of the fourth elastic part away from the slide rail, and the key is located between the barrier member and the third elastic part.

12. The server installation structure according to claim 11, wherein a third guiding structure is arranged on one side of the key away from the barrier member, and the third guiding structure is configured to guide the key when the server moves out of the accommodating cavity.

13. The server installation structure according to claim 11, wherein a pressing mark is arranged on the key, and the pressing mark is configured to indicate that the key is pressed at the pressing mark.

14. The server installation structure according to claim 11, wherein the second locking module further comprises a second spring, one end of the second spring is connected to the slide rail and the other end of the second spring is connected to the key, and an expansion and contraction direction of the spring is the same as a pressing direction of the key.

15. The server installation structure according to claim 14, wherein the fourth elastic part is provided with an avoidance hole, and the second spring passes through the avoidance hole.

16. The server installation structure according to claim 1, wherein a sliding slot is arranged on the slide rail, and a fixing member is arranged on the side of the server, and the fixing member passes through the sliding slot, and a size of the sliding slot along an extension direction of the slide rail is larger than that of the fixing member, to make the sliding slot slide relative to the slide rail.

17. The server installation structure according to claim 16, wherein a number of the sliding slots is two, and the two sliding slots are staggered.

18. A server system, wherein the server system comprises a cabinet and the server installation structure according to claim 1;
the cabinet comprises the accommodating cavity and the opening, and the opening is communicated with the accommodating cavity;
when the server is moved to the opening and installed in the accommodating cavity, the first locking module and the second locking module are both located outside the accommodating cavity, the first locking module is in the unlocked state and the second locking module is in the locked state; when the first locking module moves into the accommodating cavity with the server and the second locking module is outside the accommodating cavity, both the first locking module and the second locking module are in the locked state; when the second locking module moves to the opening with the server, the second locking module is switched from the locked state to the unlocked state, so that the server and the second locking module move into the accommodating cavity.

19. The server system according to claim 18, wherein when both the first locking module and the second locking module are located in the accommodating cavity, the first locking module is in the locked state and the second locking module is in the locked state;
when the server moves out of the accommodating cavity and the second locking module moves to the opening, the second locking module is capable to be switched from the locked state to the unlocked state.

20. The server system according to claim 18, wherein the cabinet has a first direction, a second direction and a third direction which intersect, and a first column, a second column, a third column and a fourth column are arranged in the accommodating cavity, the accommodating cavity is provided with a first cavity wall and a second cavity wall which are opposite to each other along the first direction, the first column and the second column are arranged on the first cavity wall at intervals along the second direction, the third column and the fourth column are arranged on the second cavity wall at intervals along the second direction; the first column is positioned opposite to the third column in the first direction; the second column is positioned opposite to the fourth column in the first direction; a plurality of brackets are arranged between the first column and the second column and between the third column and the fourth column; the plurality of brackets are distributed at intervals along the third direction, and the plurality of brackets extend along the direction from the opening to the interior of the accommodating cavity;
when the first locking module moves into the accommodating cavity with the server, the bracket carries the server, the server slides relative to the bracket, and the bracket acts on the first locking module to make the first locking module in the locked state.

21-24. (canceled)
